(19) United States
(12) Patent Application Publication
(10) Pub. No.: US 2010/0092875 A1
(43) Pub. Date: Apr. 15, 2010

(54) Exposure Mask for Forming Photodiode and Method of Manufacturing Image Sensor Using the Same

(76) Inventor: Woo Jin Cho, Dalseo-gu (KR)

Correspondence Address: THE LAW OFFICES OF ANDREW D. FORTNEY, PH.D., P.C., 215 W FALLBROOK AVE SUITE 203, FRESNO, CA, 93711, US

(21) Appl. No.: 12/562,691

(22) Filed: Sep. 18, 2009

(30) Foreign Application Priority Data
Oct. 14, 2008 (KR) 10-2008-0100546

(51) Int. Cl. G03F 1/00; G03F 7/20

(52) U.S. Cl. 430/5; 430/319

(57) ABSTRACT

An exposure mask for forming a photodiode of an image sensor and a method of manufacturing an image sensor using the exposure mask may be disclosed. An exposure mask for forming a photodiode of an image sensor includes a plurality of main open patterns, each having a first open pattern that is rectangular and a second open pattern extending outward from at least one corner of the first open pattern, and an open serif extending outward from each of the corners of the second open pattern that do not overlap with the first open pattern, covering a predetermined area adjacent to the second open pattern.

### CROSS REFERENCE TO RELATED APPLICATION

This application claims the benefit of Korean Patent Application No. 10-2008-0100546, filed on Oct. 14, 2008, which is hereby incorporated by reference as if fully set forth herein.

### BACKGROUND OF THE DISCLOSURE

1. Field of the Disclosure

The present invention relates to a semiconductor device, more particularly, to an exposure mask for forming an ion implantation mask used in making a photodiode region of an image sensor and a method of manufacturing an image sensor using the same.

2. Discussion of the Related Art

In general, image sensors are semiconductor devices that covert optical images into electric signals. For example, image sensors include charge coupled devices (CCD) and complementary metal oxide-silicon (CMOS) devices.

Such an image sensor may be configured into a plurality of pixel regions, each including a photodiode for sensing incident light and a logic region for processing the sensed light into an electric signal for data formation. That is, the image sensor is an imaging device that generates an electronic image from light incident on the pixel regions by using the pixel units, each including a photodiode and at least one transistor.

As the pitch of a pixel of the image sensor gets smaller, the area of the photodiode is reduced more and more. Such photodiode area reductions may cause light degradation. To solve such a disadvantage, a shared pixel is used. For example, a two-pixel shared structure may be used, in which 2 photodiodes share part of a logic region (e.g., a reset transistor, drive transistor and a select transistor of a 4-transistor unit pixel).

FIG. 1 is a diagram illustrating photodiode implant regions in a conventional shared pixel structure, and FIG. 2 is an enlarged view illustrating a single implant region from FIG. 1.

When manufacturing an image sensor manufactured using a 0.11 μm IC fabrication technology, an apparatus that generates middle ultraviolet (MUV) radiation may be used to form an ion implantation mask pattern for a relatively large patterned photodiode region. The MUV apparatus cannot secure an overlay margin with a gate which formed adjacent to (and/or partially over) the photodiode region because of its mechanical limit(s), and the overlay margin is unreliable if the image sensor is manufactured using such an MUV apparatus.

In reference to FIGS. 1 and 2, implanted photodiode regions 102, 104, 106 and 108 may not have the desired pattern because of the limitation(s) of the MUV apparatus. Especially, there is severe distortion near corners. As shown in FIG. 2, a profile of a predetermined region 210 which will be adjacent to gates 105 and 110 has a curvature because of the limit(s) of the MUV apparatus. As a result, if there is a small alignment variance in the formation of the photodiode region 106 and the gate 110, there can be a relatively large variance in the overlapping area 210 which can greatly influence the performance characteristics of the image sensor. Notably, the reliability of the image sensor may deteriorate significantly.

### SUMMARY OF THE DISCLOSURE

Accordingly, the present invention is directed to an exposure mask for forming a photodiode of an image sensor and a method of manufacturing an image sensor using the same.

An object of the present invention is to provide an exposure mask which enables a photodiode region of an image sensor (particularly an image sensor having a shared pixel structure) to have a uniform corner doping pattern, and to provide a method of making an image sensor using the exposure mask.

Additional advantages, objects, and features of the disclosure will be set forth in part in the description which follows and in part will become apparent to those skilled in the art upon examination of the following or may be learned from practice of the invention. The objectives and other advantages of the invention may be realized and attained by the structure(s) particularly pointed out in the written description and claims hereof as well as the appended drawings.

To achieve this object and other advantages and in accordance with the purpose(s) of the invention, as embodied and broadly described herein, an exposure mask for forming a photodiode of an image sensor may include a plurality of main open patterns comprising a first open pattern that has a rectangular shape and a second open pattern extending outward from at least one corner of the first open pattern; and an open serif extending outward from a plurality of corners of the second open pattern.

In another aspect of the present invention, a method of manufacturing an image sensor may include; forming a photoresist on an image sensor substrate, the image sensor substrate having a shared pixel region; forming a photoresist pattern by exposing and developing the photoresist using an exposure mask, the exposure mask including a plurality of main open patterns, each comprising a first open pattern that has a rectangular shape and a second open pattern extending outward from at least one corner of the first open pattern, and an open serif extending outward from a plurality of corners of the second open pattern; and forming a photodiode region by implanting impurity ions in the substrate using the photoresist pattern as a mask.

According to the present invention, a serif is further provided, and thus, a change in the area of overlap between a transfer gate and a photodiode is uniform, even with misalignment variances caused by the limit(s) of a middle ultraviolet (MUV) irradiation apparatus. As a result, the present invention may secure uniform overlap margin.

It is to be understood that both the foregoing general description and the following detailed description(s) of the present invention are exemplary and explanatory and are intended to provide further explanation of the invention as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle(s) of the disclosure. In the drawings:

FIG. 1 is a diagram illustrating an exemplary partial implant layout of a conventional photodiode in an image sensor having a shared pixel structure;

FIG. 2 is an enlarged view partially illustrating the layout shown in FIG. 1;

FIG. 3A is a diagram illustrating an exemplary unit pattern of an exemplary exposure mask for forming a photodiode of an image sensor according to an embodiment of the present invention;

FIG. 3B is a diagram illustrating an implant profile of the photodiode formed by the exposure mask shown in FIG. 3A;

FIG. 3C is a diagram illustrating alignment of the exemplary unit patterns shown in FIG. 3A;

FIG. 4A is a diagram illustrating an exemplary unit pattern of an exemplary exposure mask for forming a photodiode of an image sensor according to another embodiment of the present invention;

FIG. 4B is a diagram illustrating the implant region for the photodiode formed by the exemplary exposure mask shown in FIG. 4A;

FIG. 4C is a diagram illustrating alignment of the unit patterns shown in FIG. 4A; and

FIGS. 5A to 5E are cross-sectional views illustrating a method of manufacturing the image sensor according to an exemplary embodiment.

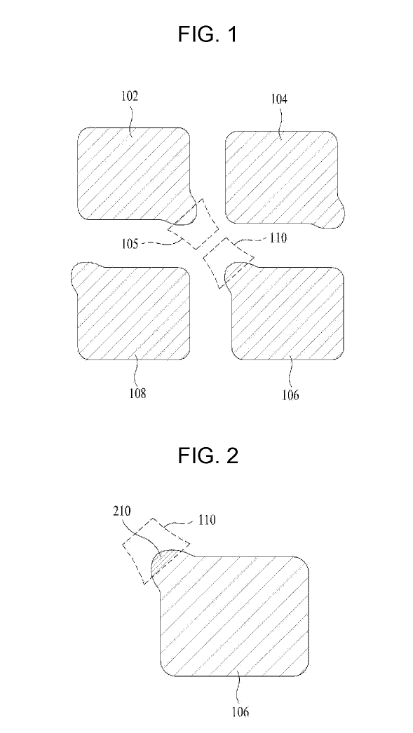

### DETAILED DESCRIPTION

Reference will now be made in detail to embodiments of the present invention, examples of which are illustrated in the accompanying drawings. Wherever possible, the same reference numbers will be used throughout the drawings to refer to the same or like parts.

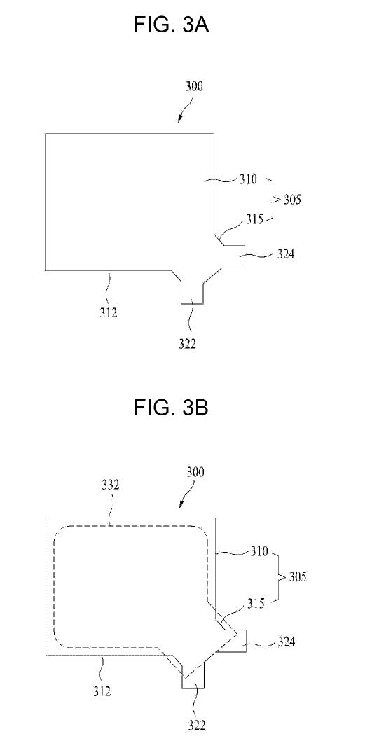

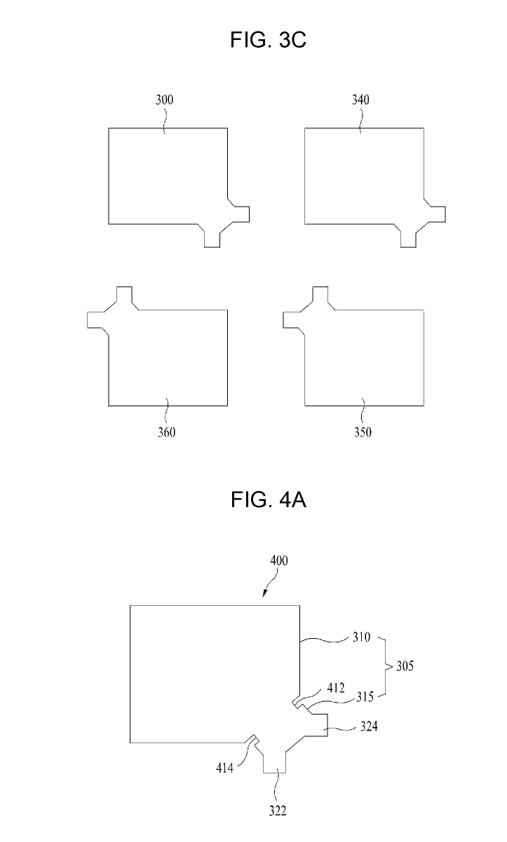

FIG. 3A is a diagram illustrating an exemplary unit pattern of an exposure mask for forming a photodiode of an image sensor according to an exemplary embodiment of the present invention. FIG. 3B is a diagram illustrating the implant region or profile of the photodiode that is formed using the exemplary exposure mask shown in FIG. 3A. FIG. 3C is a diagram illustrating the alignment of unit patterns shown in FIG. 3A.

In reference to FIGS. 3A to 3C, the exposure mask for forming the photodiode of the image sensor includes a plurality of unit patterns 300, 340, 350 and 360. Each of the unit patterns (for example, the pattern 300 in FIG. 3A) includes a main open pattern 305 and open serifs 322 and 324. That is, the exposure mask for forming the photodiode for the image sensor includes a plurality of main open patterns including 305, for example.

Each of the plural main open patterns 305, for example, includes a first open pattern 310 that has a rectangular shape and a second open pattern 315 extending (or comprising a projection) outward from at least one corner of the first open pattern 310. Thus, the second open pattern 315 covers a predetermined area adjacent to the corner(s) of the first open pattern 310. Here, the second open pattern 315 may have a rectangular shape (for example, a regular square shape).

For example, the second open pattern 315 may extend or project from at least one corner of the first open pattern 310 along an oblique line from the center of the first open pattern 310 through the corresponding corner of the first open pattern 310. In general, the oblique line bisects the second open pattern 315.

The open serifs 322 and 324 extend (e.g., each comprise a projection) outward from at least one corner of the second open pattern 315. In one exemplary embodiment, the open serifs 322 and 324 extend from each corner of the second open pattern 315 that, in turn, extends from the first open pattern 310. The open serifs 322 and 324 cover a predetermined area adjacent to the corner(s) of the second open pattern 310. Here, each of the open serifs 322 and 324 may have a rectangular shape (e.g., a square shape) having a length and a width of 200 nm˜300 nm. Also, the open serifs 322 and 324 may overlap the at least one corner of the second open pattern 315 in a center or internal region of the open serifs 322 and 324. In one example, the open serifs 322 and 324 may extend or be positioned perpendicularly to a side 312 of the first open pattern 310 of the main open pattern 305.

According to the profile of the implant region 332 of the photodiode shown in FIG. 3B, the implant area which will be adjacent to (or overlaid with) a gate is uniform as a result of the open serifs. Even with performing an exposure process with a MUV device that irradiates light having a wavelength of 250 nm˜400 nm, a uniform area of overlap with both the gate and the photodiode may be gained. Even if there is nonalignment because of the limit of the MUV device, the profile of the photodiode border is uniform, and thus, the area of overlap between the gate and the photodiode is sufficiently uniform to secure a uniform overlap margin.

The exposure mask according to embodiments of the present invention is used to form a photosensitive layer pattern for subsequent ion implantation to form a photodiode of an image sensor.

The unit pattern 300 shown in FIG. 3A is aligned in a predetermined manner with other unit patterns (e.g., 340, 350 and 360 in FIG. 3C) to form a mask pattern. As shown in FIG. 3C, neighboring unit patterns 300, 340, 350 and 360 can be symmetrical with respect to each other. For example, the four neighboring unit patterns 300, 340, 350 and 360 may be symmetric with respect to an X-axis and a Y-axis of XY coordinates, that is, symmetric with respect to the origin. Alternatively, the four neighboring unit patterns 300, 340, 350 and 360 may have one or more C₂ axes of symmetry (e.g., in the center of the four neighboring unit patterns 300, 340, 350 and 360; between adjacent unit patterns 300 and 360, or 340 and 350, in the “columns” shown in FIG. 3C; etc. In a further alternative, unit patterns 340 and 360 may be “flipped” so that the second open pattern and the open serifs face the second open pattern and the open serifs of the adjacent unit patterns 300 and 350, in which case the neighboring unit patterns 300, 340, 350 and 360 may have one or more C₄ axes of symmetry (e.g., when the four neighboring unit patterns include a substantially square first open pattern).

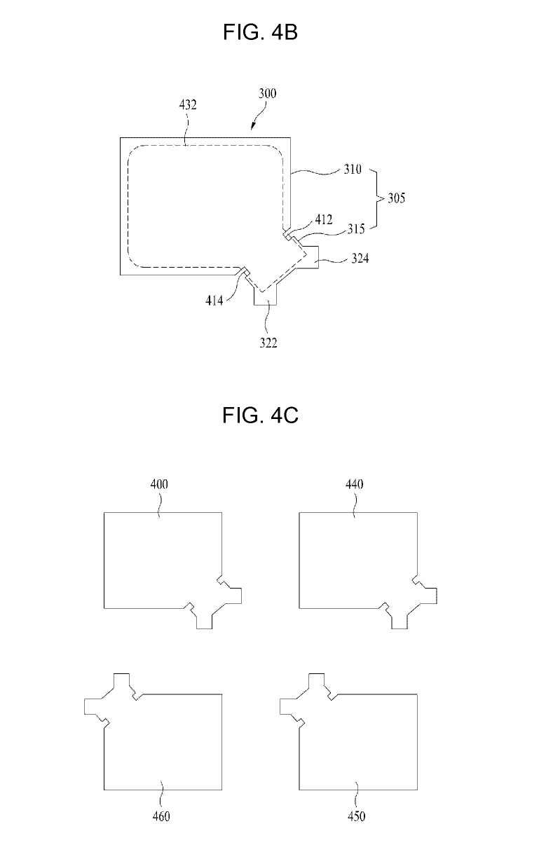

FIG. 4A illustrates an exemplary unit pattern 400 of an exposure mask for forming a photodiode of an image sensor according to another embodiment of the present invention. FIG. 4B illustrates the profile of the implant region of the photodiode formed using the exposure mask shown in FIG. 4A. FIG. 4C illustrates the alignment of unit patterns 400, 440, 450 and 460 shown in FIG. 4A.

In reference to FIGS. 4A to 4C, the unit pattern 400 includes a main pattern 305 including a first open pattern 310 and a second open pattern 315 (for example, the same as or substantially similar to FIG. 3A) and open serifs 322 and 324 (e.g., as shown in FIG. 3A). Here, according to this further embodiment, the unit pattern further includes light shielding serifs 412 and 414 adjacent to each corner or intersection between the first open pattern 310 and the second open pattern 315. Here, the light shielding serifs 412 and 414 shut off the transmission of the light. Light shielding serifs 412 and 414 may have a rectangular shape (for example, a square shape). Also, light shielding serifs 412 and 414 may extend into the first and second open patterns 310 and 315 along a line perpendicular to the edge of the second open pattern 315, generally at or proximate to the intersection of the first and second open patterns 310 and 315. The angle between edges of the first and second open patterns 310 and 315 at the intersection thereof may be from 30° to 60°, for example.

According to the profile of the implant region 432 of the photodiode shown in FIG. 4B, the photodiode area overlapping with (or extending alongside) a gate is uniform because of the open serifs 322 and 324, and a corner rounding profile of the area adjacent to the intersection(s) between the first open pattern 310 and the second open pattern 315 may be improved.

As shown in FIG. 4C, the alignment between neighboring unit patterns (e.g., 400, 440, 450 and 460) may be as described above for the unit patterns in FIG. 3C. For example, the unit patterns 400, 440, 450 and 460 may be symmetric with respect to an X-axis and a Y-axis of XY coordinates (that is, symmetric with respect to the origin).

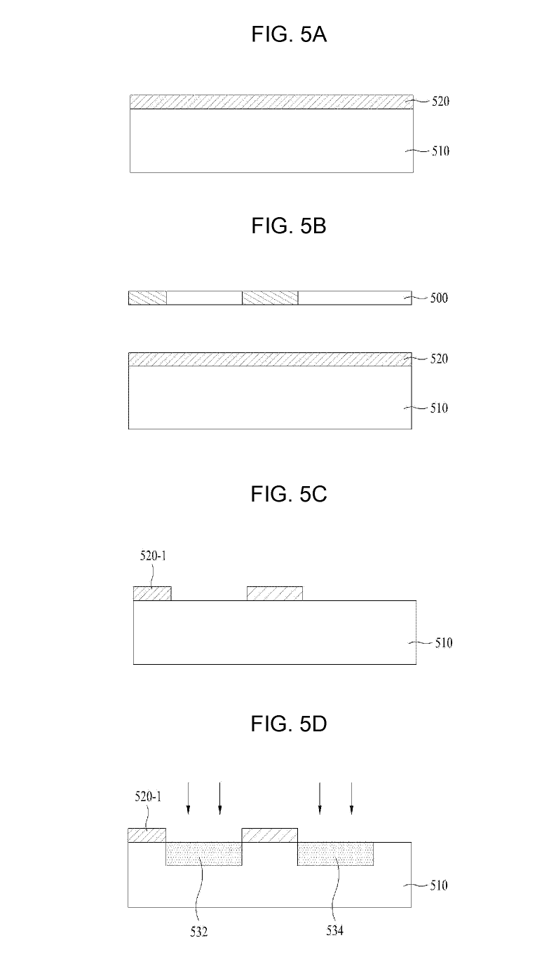

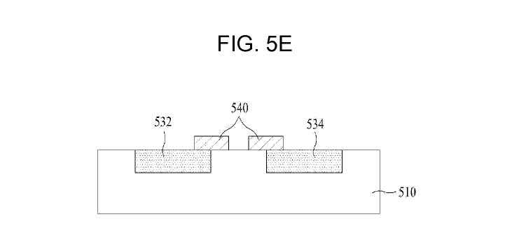

FIGS. 5A to 5E are cross-sectional views illustrating an exemplary method of manufacturing an image sensor according to embodiment(s) of the present invention.

In reference to FIG. 5A, a substrate 510 (e.g., single-crystal silicon, which may have one or more epitaxial silicon layers grown thereon) is provided to form an image sensor that may have one or more shared pixels therein. The substrate 510 may thus be a silicon substrate with one or more isolation regions therein. Then, a photoresist 520 is coated on the substrate 510 by a spin coating method.

As shown in FIGS. 5B and 5C, the photoresist 520 is exposed and developed using an exposure mask 500 such that a photoresist pattern 520-1 is formed on the substrate 510.

A light source used in the exposure process may be an ultraviolet light source providing light having a wavelength of 250 nm˜400 nm. A middle ultraviolet exposure device is used for that. At this time, the exposure mask 500 is an exposure mask shown in FIG. 3C or FIG. 4C.

Hence, as shown in FIG. 5D, one or more impurity ions, for example, an n-type impurity ion is implanted into the substrate 510 using the photoresist pattern 520-1 as ion implantation mask. After annealing (and optionally, forming the transistor gates [see FIG. 5E] and implanting a p-type impurity ion), photodiodes 532 and 534 may be formed. Here, a border or layout of the implant region of the photodiode 532 and 534 is shown in FIGS. 3B and 4B.

Next, as shown in FIG. 5E, an ashing process is performed on the photoresist pattern 520-1 such that the photoresist pattern 520-1 is removed. Then, a gate pattern 540 which may overlaps with predetermined area of the photodiodes 532 and 534 is formed on the substrate 510. The area of overlap may be a predetermined area.

As mentioned above, if the photodiodes are formed using a mask according to embodiments of the present invention, the implant area of the photodiodes overlapping with the gates is relatively uniform. As a result, even if there is misalignment because of the limit(s) of the MUV device, variance in the overlapping area between the gates and the photodiodes is sufficiently uniform to secure a uniform overlap margin.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. An exposure mask for forming a photodiode of an image sensor comprising:
a plurality of main open patterns comprising a first open pattern that is rectangular shaped and a second open pattern comprising an outward projection from at least one corner of the first open pattern; and
an open serif extending outward from a plurality of corners of the second open pattern.

2. The exposure mask of claim 1, wherein each of the first open patterns has a rectangular shape.

3. The exposure mask of claim 2, wherein each of the second open patterns has a rectangular shape.

4. The exposure mask of claim 1, wherein the second open pattern has a square shape.

5. The exposure mask of claim 1, wherein the open serif has a square shape, and the second pattern has a corner in an internal region of the open serif.

6. The exposure mask of claim 5, comprising a plurality of the open serifs.

7. The exposure mask of claim 1, further comprising:
a light shielding serif in a predetermined area adjacent to an intersection of the first open pattern with the second open pattern.

8. The exposure mask of claim 1, wherein four neighboring main open patterns of the plurality of the main open patterns are symmetric to each other.

9. The exposure mask of claim 4, wherein the second open pattern is oblique to one of the corners of the first open pattern from a center of the first open pattern.

10. The exposure mask of claim 5, wherein the open serif is perpendicular to a side of the first open pattern adjacent thereto.

11. A method of manufacturing an image sensor comprising:
forming a photoresist on an image sensor substrate, the image sensor substrate having a shared pixel region;
forming a photoresist pattern by exposing and developing the photoresist using an exposure mask, the exposure mask comprising:
a plurality of main open patterns comprising a first open pattern that has a rectangular shape and a second open pattern extending outward from at least one corner of the first open pattern; and
an open serif extending outward from a plurality of corners of the second open pattern; and
forming a photodiode region by implanting impurity ions in the substrate using the photoresist pattern as an implant mask.

12. The method of claim 11, wherein forming the photoresist pattern comprises irradiating the photoresist with middle ultraviolet (MUV) irradiation.

13. The method of claim 11, wherein the exposure mask further comprises:
a light shielding serif formed in a predetermined area adjacent to an intersection of the first open pattern with the second open pattern.

14. The method of claim 11, further comprising preparing the substrate to have an image sensor formed thereon, the image sensor comprising the shared pixel region.

15. The method of claim 11, wherein exposing and developing the photoresist comprises irradiating the photoresist with ultraviolet (UV) irradiation and removing either an irradiated portion or a non-irradiated portion of the photoresist with a developer.

16. The method of claim 11, wherein the second open pattern has a square shape.

17. The method of claim 11, wherein the open serif has a square shape, and the second pattern has a corner in an internal region of the open serif.

18. The method of claim 17, wherein the open serif is perpendicular to a side of the first open pattern adjacent thereto.
